(19) United States
(12) Patent Application Publication
(10) Pub. No.: US 2026/0238206 A1
(43) Pub. Date: Aug. 13, 2026

(54) SEMICONDUCTOR DEVICE, ELECTRONIC DEVICE, AND VEHICLE

(71) Applicant: ROHM CO., LTD., Kyoto-shi (JP)

(72) Inventor: Koki MISHIMA, Kyoto-shi (JP)

(21) Appl. No.: 19/181,969

(22) Filed: Apr. 17, 2025

(30) Foreign Application Priority Data
Apr. 17, 2024 (JP) 2024-066791

(51) Int. Cl. H03K 17/687; B60L 15/00; H01F 27/28; H02M 1/088

(52) U.S. Cl. CPC H03K 17/6871; H01F 27/2804; H02M 1/088; B60L 15/007; H01F 2027/2809

(57) ABSTRACT

A semiconductor device includes: a drive circuit configured to perform one of turn-on and turn-off of a switching device to be driven at a time of normal driving; and an active discharge circuit configured to perform one of soft turn-on and soft turn-off of the switching device more mildly than the one of the turn-on and the turn-off by the drive circuit at a time of active discharge.

### CROSS-REFERENCE TO RELATED APPLICATIONS

The present invention claims priority under 35 U.S.C. § 119 to Japanese Patent Application No. 2024-066791 filed on Apr. 17, 2024, the entire content of which is incorporated herein by reference.

### BACKGROUND

### 1. Technical Field

The present disclosure relates to semiconductor devices, electronic devices, and vehicles.

### 2. Description of Related Art

Hitherto, signal transmission devices that transmit a signal between a primary circuit system and a secondary circuit system while electrically isolating between the primary circuit system and the secondary circuit system are used in various applications (e.g., power supply devices and motor driving devices).

Note that, WO-A-2022/070944 made by the present applicant can be cited as one example of the related art that relates to the above description.

### BRIEF DESCRIPTION OF DRAWINGS

FIG. 1 is a diagram illustrating the basic configuration of a signal transmission device;

FIG. 2 is a diagram illustrating the basic structure of a transformer chip;

FIG. 3 is a perspective view of a semiconductor device used as a two-channel transformer chip;

FIG. 4 is a plan view of the semiconductor device shown in FIG. 3;

FIG. 5 is a plan view of a layer in the semiconductor device shown in FIG. 3 where low-potential coils are formed;

FIG. 6 is a plan view of a layer in the semiconductor device shown in FIG. 3 where high-potential coils are formed;

FIG. 7 is a cross-sectional view taken along line VIII-VIII shown in FIG. 6;

FIG. 8 is an enlarged view (showing a separation structure) of region XIII shown in FIG. 7;

FIG. 9 is a diagram schematically showing an example of the layout of a transformer chip;

FIG. 10 is a diagram showing the overall configuration of an electronic device;

FIG. 11 is a diagram showing a first embodiment (a comparative example) of the electronic device;

FIG. 12 is a chart showing active discharge of the first embodiment;

FIG. 13 is a diagram showing a second embodiment of the electronic device;

FIG. 14 is a chart showing active discharge of the second embodiment;

FIG. 15 is a diagram showing a third embodiment of the electronic device;

FIG. 16 is a diagram showing a fourth embodiment of the electronic device;

FIG. 17 is a table showing the input/output logic of the semiconductor device;

FIG. 18 is a chart showing active discharge of the fourth embodiment;

FIG. 19 is a diagram showing a configuration example of the semiconductor device;

FIG. 20 is a chart showing an example of soft turn-on control;

FIG. 21 is a chart showing an example of soft turn-off control; and

FIG. 22 is an exterior view of a vehicle.

### DETAILED DESCRIPTION

### Signal Transmission Device (Basic Configuration)

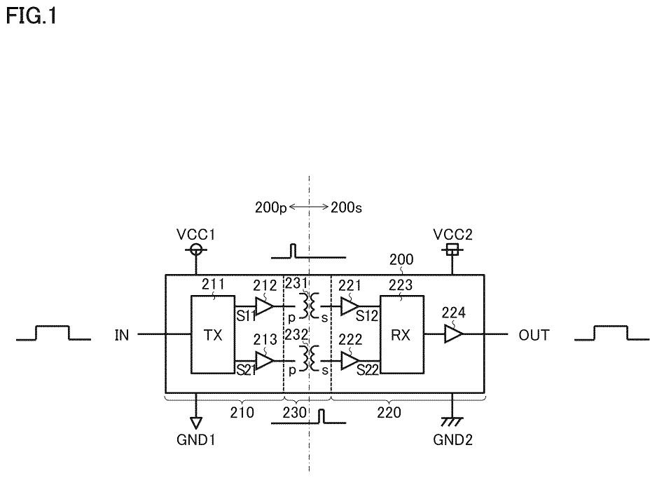

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

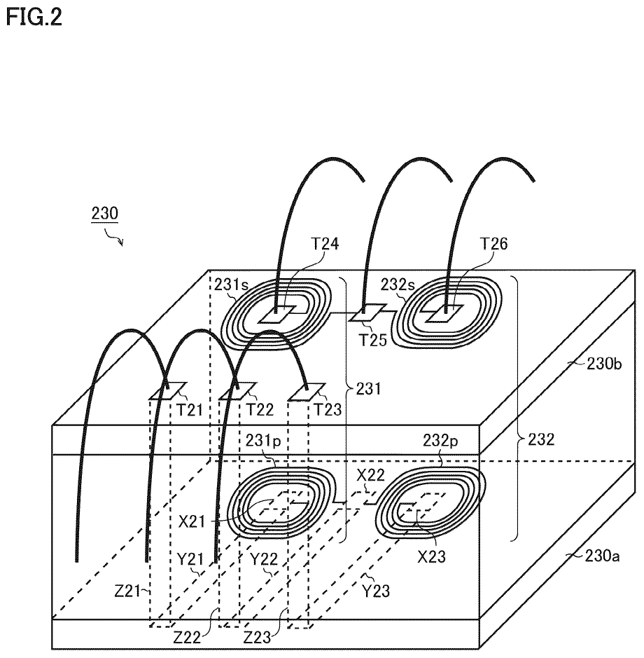

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 231s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

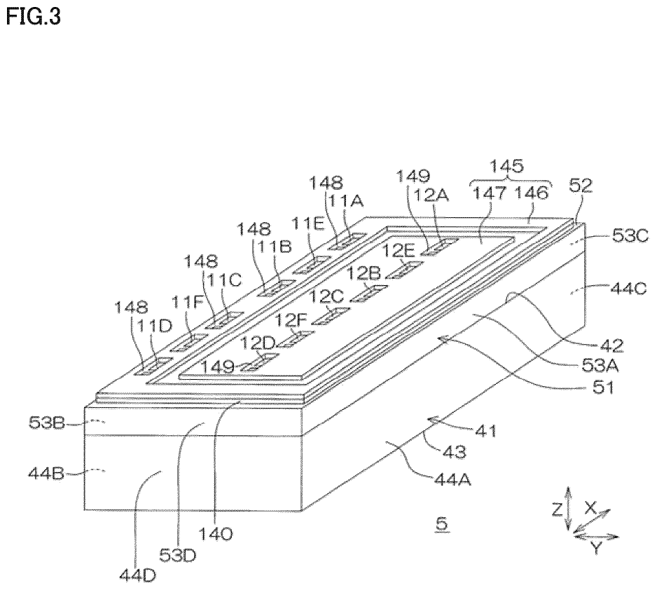

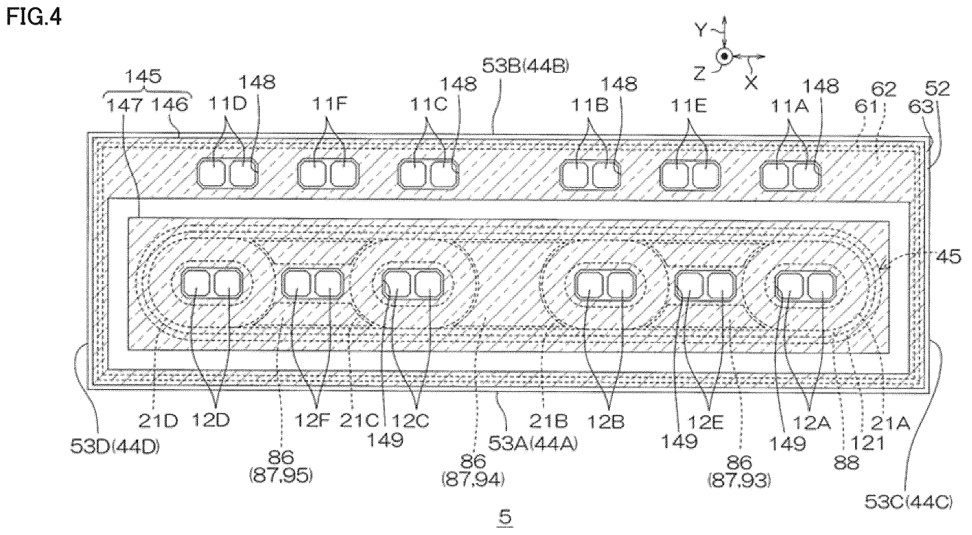

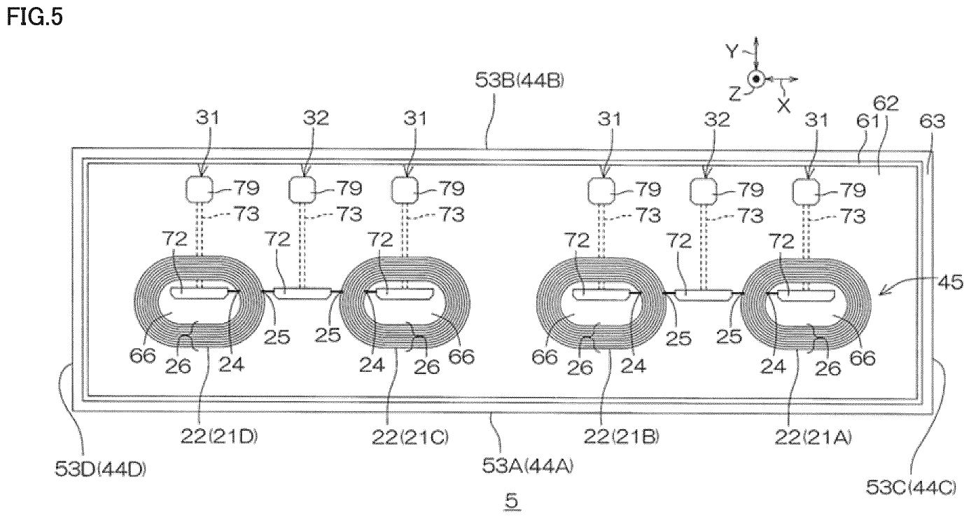

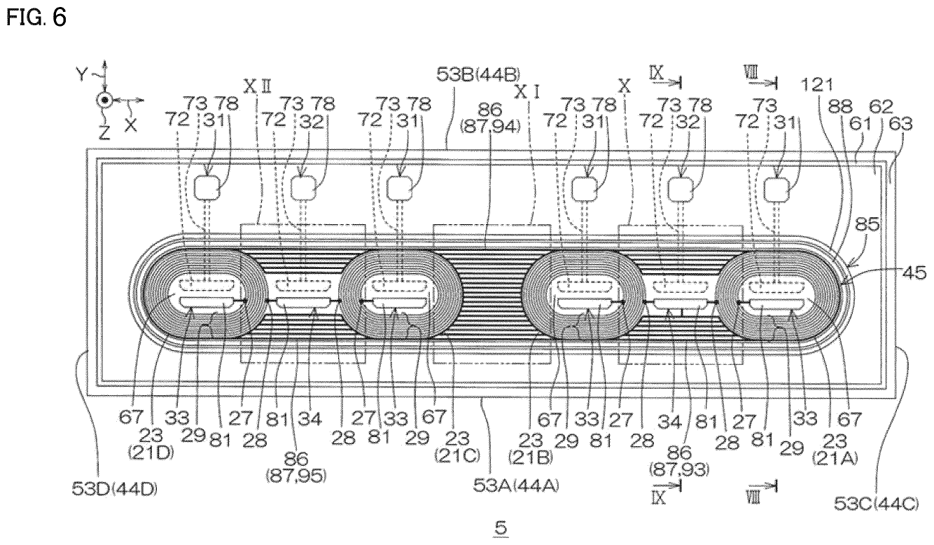

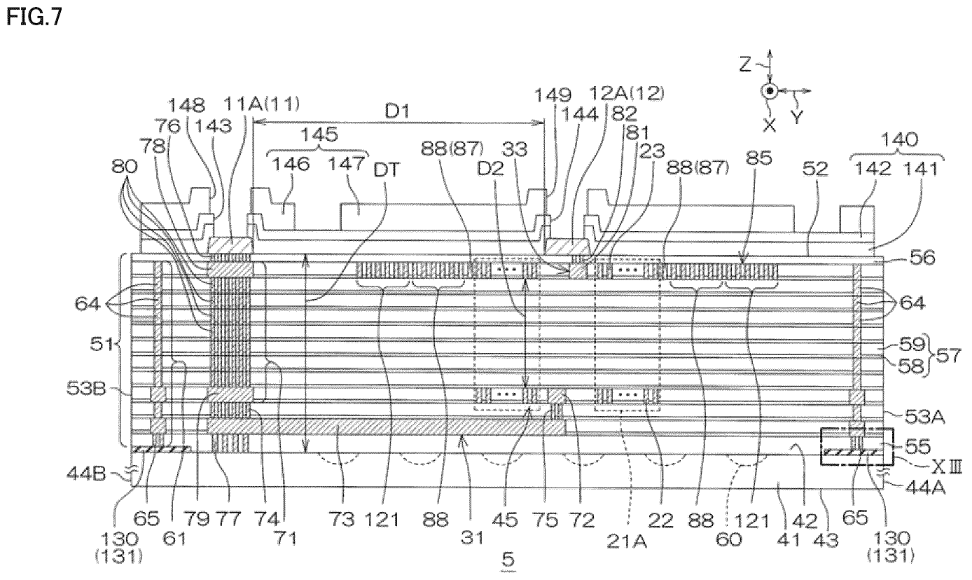

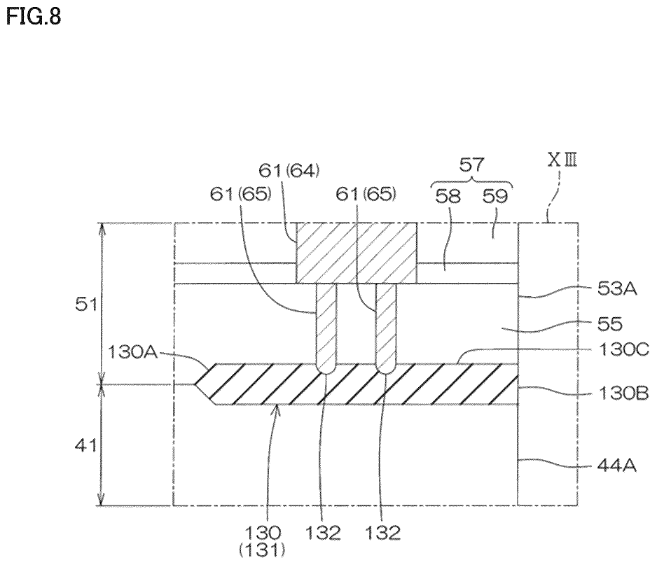

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D includes a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73 and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41 and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61 and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible suppress unnecessary conduction between the high-potential terminal 12 and the sealing conductor 61. Likewise, in a case where a voltage is applied to the second functional device 60 via the low-and high-potential terminals 11 and 12, it is possible suppress unnecessary conduction between the low-potential terminal 11 and the sealing conductor 61.

The embodiment described above deals with an example where a second functional device 60 is formed. The second functional device 60 however is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

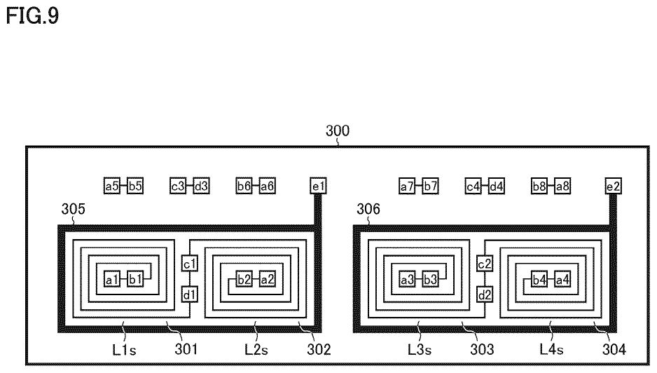

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 302, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Electronic Device (Overall Configuration)

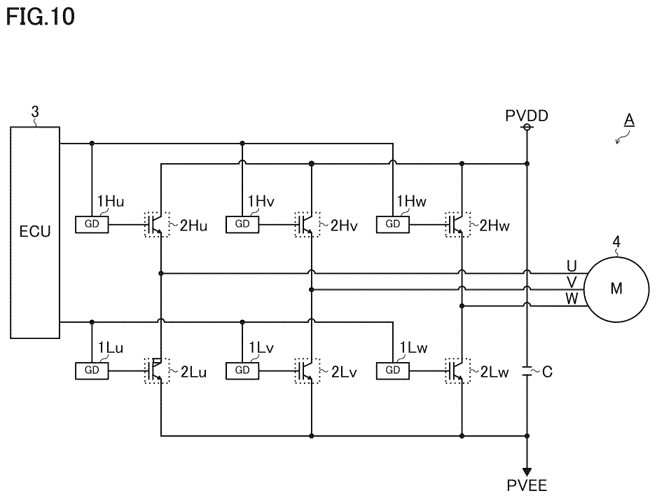

FIG. 10 is a diagram showing the overall configuration of an electronic device. The electronic device A includes high-side gate driver ICs 1H(u/v/w), low-side gate driver ICs 1L(u/v/w), high-side power transistors 2H(u/v/w), low-side power transistors 2L(u/v/w), an ECU [electronic control unit] 3, a motor 4, and a capacitor C.

The high-side gate driver ICs 1H(u/v/w), while isolating between the ECU 3 and the high-side power transistors 2H(u/v/w), respectively drive the high-side power transistors 2H(u/v/w) by generating high-side gate drive signals according to high-side gate control signals to be input from the ECU 3.

The low-side gate driver ICs 1L(u/v/w), while isolating between the ECU 3 and the low-side power transistors 2L(u/v/w), respectively drive the low-side power transistors 2L(u/v/w) by generating low-side gate drive signals according to low-side gate control signals to be input from the ECU 3.

Note that, the signal transmission device 200 described previously can be suitably used as the high-side gate driver ICs 1H(u/v/w) and the low-side gate driver ICs 1L(u/v/w).

The high-side power transistors 2H(u/v/w) are respectively connected, as high-side switching devices that form half-bridge output stages for three phases (U-phase/V-phase/W-phase), between the application terminal for a first supply voltage PVDD and the input terminals for the respective phases of the motor 4.

The low-side power transistors 2L(u/v/w) are respectively connected, as low-side switching devices that form the half-bridge output stages for the three phases (U-phase/V-phase/W-phase), between the input terminals for the respective phases of the motor 4 and the application terminal for a second supply voltage PVEE.

In the diagram, an IGBT [insulated gate bipolar transistor] is used as each of the high-side power transistors 2H(u/v/w) and the low-side power transistors 2L(u/v/w). However, the high-side power transistors 2H(u/v/w) and the low-side power transistors 2L(u/v/w) may each be replaced with a Si device, a SiC device, or a GaN device.

The ECU3 controls the rotation driving of the motor 4 by driving all the high-side power transistors 2H(u/v/w) and the low-side power transistors 2L(u/v/w) via the high-side gate driver ICs 1H(u/v/w) and the low-side gate driver ICs 1L(u/v/w).

The motor 4 is a three-phase motor that is driven to rotate according to three-phase drive voltages U/V/W to be input respectively from the half-bridge output stages for the three phases (U-phase/V-phase/W-phase).

The capacitor C is connected in parallel to the half-bridge output stages between the application terminal for the first supply voltage PVDD and the application terminal for the second supply voltage PVEE.

In this way, the signal transmission device 200 (isolated gate driver IC) is applicable, for example, to inverter circuits for motor driving.

### Investigation of Discharge from Capacitor C

Incidentally, in a case where the capacitor C described above needs to be discharged, commonly, a high-withstand-voltage switch for short-circuiting between the application terminal for the first supply voltage PVDD and the application terminal for the second supply voltage PVEE and a current limiting resistor for limiting current that flows through the high-withstand-voltage switch are prepared (both unillustrated in FIG. 10). However, both the high-withstand-voltage switch and the current limiting resistor are expensive.

In view of the investigation described above, in the following description, an embodiment in which the capacitor C can be discharged without need for the high-withstand-voltage switch, or the current limiting resistor is proposed.

### Electronic Device (First Embodiment)

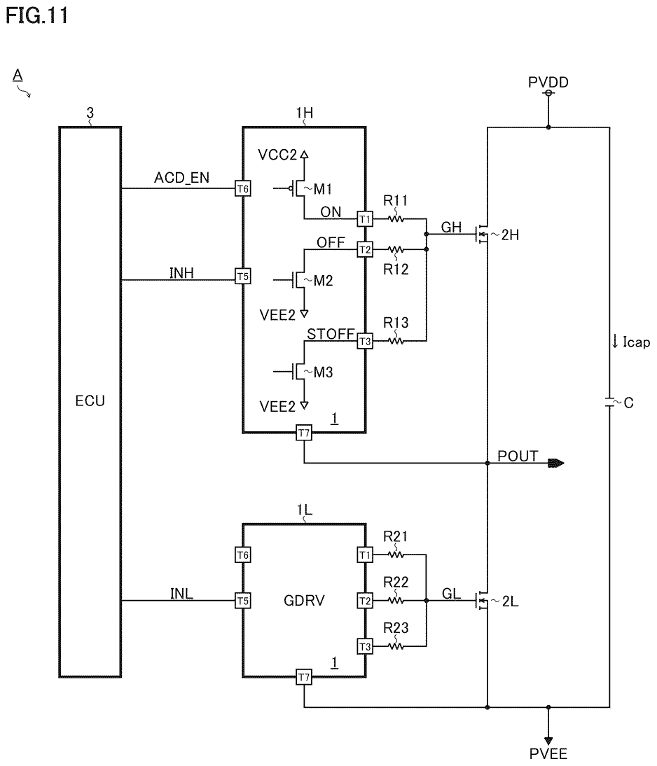

FIG. 11 is a diagram showing a first embodiment (corresponding to a comparative example that is compared to a second embodiment to a fourth embodiment described subsequently) of the electronic device A. The electronic device A of this embodiment is basically the same as that shown in FIG. 10 referred to previously except including the same semiconductor devices 1 respectively as the high-side gate driver IC 1H and the low-side gate driver IC 1L.

The high-side power transistor 2H and the low-side power transistor 2L correspond to a first switching device and a second switching device that form a half-bridge output stage by being connected in series between the application terminal for the first supply voltage PVDD and the application terminal for the second supply voltage PVEE. The high-side gate driver IC 1H corresponds to a first driving device that drives the high-side power transistor 2H. The low-side gate driver IC 1L corresponds to a second driving device that drives the low-side power transistor 2L.

Note that, the high-side gate driver IC 1H, the low-side gate driver IC 1L, the high-side power transistor 2H, and the low-side power transistor 2L may each be for any of the U-phase, the V-phase, and the W-phase. That is, an output voltage POUT that develops at a connection node between the source of the high-side power transistor 2H and the drain of the low-side power transistor 2L may be for any of the three-phase drive voltages U/V/W.

The high-side gate driver IC 1H and the low-side gate driver IC 1L each include a transistor M1 (e.g., a P-channel MOSFET [metal oxide semiconductor field effect transistor], a transistor M2 (e.g., an N-channel MOSFET), a transistor M3 (e.g., an N-channel MOSFET), and external terminals T1, T2, and T3 and T5, T6, and T7. Note that, resistors R11, R12, and R13 are attached to the high-side gate driver IC 1H. Likewise, resistors R21, R22, and R23 are attached to the low-side gate driver IC 1L.

The transistor M1 establishes/blocks conduction between the application terminal for a positive supply voltage VCC2 and the external terminal T1. The resistor R11 is attached between the external terminal T1 of the high-side gate driver IC 1H and the gate of the high-side power transistor 2H. The resistor R21 is attached between the external terminal T1 of the low-side gate driver IC 1L and the gate of the low-side power transistor 2L. The external terminals T1 can be understood as turn-on output terminals at the time of normal driving.

The transistor M2 establishes/blocks conduction between the application terminal for a negative supply voltage VEE2 and the external terminal T2. The resistor R12 is attached between the external terminal T2 of the high-side gate driver IC 1H and the gate of the high-side power transistor 2H. The resistor R12 may have a resistance value that is the same as or different from that of the resistor R11. The resistor R22 is attached between the external terminal T2 of the low-side gate driver IC 1L and the gate of the low-side power transistor 2L. The resistor R22 may have a resistance value that is the same as or different from that of the resistor R21. The external terminals T2 can be understood as turn-off output terminals at the time of the normal driving.

The transistor M3 establishes/blocks conduction between the application terminal for the negative supply voltage VEE2 and the external terminal T3. The resistor R13 is attached between the external terminal T3 of the high-side gate driver IC 1H and the gate of the high-side power transistor 2H. The resistor R13 has a resistance value higher than that of the resistor R12. The resistor R23 is attached between the external terminal T3 of the low-side gate driver IC 1L and the gate of the low-side power transistor 2L. The resistor R23 has a resistance value higher than that of the resistor R22. The external terminals T3 can be understood as soft turn-off output terminals.

Note that, a high-side gate drive signal GH is applied to the gate of the high-side power transistor 2H. A low-side gate drive signal GL is applied to the gate of the low-side power transistor 2L.

The external terminal T5 of the high-side gate driver IC 1H is connected to the application terminal for a high-side input pulse signal INH. The external terminal T5 of the low-side gate driver IC 1L is connected to the application terminal for a low-side input pulse signal INL. The external terminals T5 can be understood as input terminals.

The external terminal T6 of the high-side gate driver IC 1H is connected to the application terminal for an active-discharge control signal ACD_EN. The external terminal T6 of the low-side gate driver IC 1L is in an open state or a pull-down state. The external terminals T6 can be understood as active-discharge control terminals.

The external terminal T7 of the high-side gate driver IC 1H is connected to the application terminal for the output voltage POUT. The external terminal T7 of the low-side gate driver IC 1L is connected to the application terminal for the second supply voltage PVEE. The external terminals T7 can be understood as reference voltage terminals (grounded terminals).

The ECU 3 generates all the high-side input pulse signal INH, the low-side input pulse signal INL, and the active-discharge control signal ACD_EN. That is, the ECU 3 corresponds to a control device that controls the high-side gate driver IC 1H and the low-side gate driver IC 1L.

### Turn-On/Turn-Off/Soft Turn-Off

In order to perform turn-on of the high-side power transistor 2H, the high-side gate driver IC 1H turns on the transistor M1 and turns off the transistors M2 and M3. At this time, current flows from the application terminal for the positive supply voltage VCC2 to the gate of the high-side power transistor 2H via the transistor M1 and the resistor R11. Thus, the high-side gate drive signal GH, that is, an applied voltage ON to the external terminal T1 rises from low level to high level. As a result, the high-side power transistor 2H is subjected to the turn-on. A slew rate of the high-side gate drive signal GH at the time of the turn-on can be adjusted according to the resistance value of the resistor R11.

Likewise, in order to perform turn-off of the high-side power transistor 2H, the high-side gate driver IC 1H turns on the transistor M2 and turns off the transistors M1 and M3. At this time, current flows from the gate of the high-side power transistor 2H to the application terminal for the negative supply voltage VEE2 via the resistor R12 and the transistor M2. Thus, the high-side gate drive signal GH, that is, an applied voltage OFF to the external terminal T2 falls from high level to low level. As a result, the high-side power transistor 2H is subjected to the turn-off. A slew rate of the high-side gate drive signal GH at the time of the turn-off can be adjusted according to the resistance value of the resistor R12.

Moreover, in order to perform soft turn-off of the high-side power transistor 2H, the high-side gate driver IC 1H turns on the transistor M3 and turns off the transistors M1 and M2. At this time, current flows from the gate of the high-side power transistor 2H to the application terminal for the negative supply voltage VEE2 via the resistor R13 and the transistor M3. Thus, the high-side gate drive signal GH, that is, an applied voltage STOFF to the external terminal T3 falls from high level to low level. As a result, the high-side power transistor 2H is subjected to the soft turn-off. A slew rate of the high-side gate drive signal GH at the time of the soft turn-off can be adjusted according to the resistance value of the resistor R13. Note that, the slew rate at the time of the soft turn-off is lower than the slew rate at the time of the normal turn-off.

The same applies to the low-side gate driver IC 1L. That is, a slew rate of the low-side gate drive signal GL at the time of turn-on, a slew rate of the same at the time of turn-off, and a slew rate of the same at the time of the soft turn-off can respectively be adjusted according to respective resistance values of the resistors R21 to R23.

Moreover, in the electronic device A, both the high-side gate driver IC 1H and the low-side gate driver IC 1L are controlled so as to discharge the capacitor C via the high-side power transistor 2H and the low-side power transistor 2L for one phase without the need for the high-withstand-voltage switch or the current limiting resistor. Such discharge control is called “active discharge.”

### Active Discharge (First Embodiment)

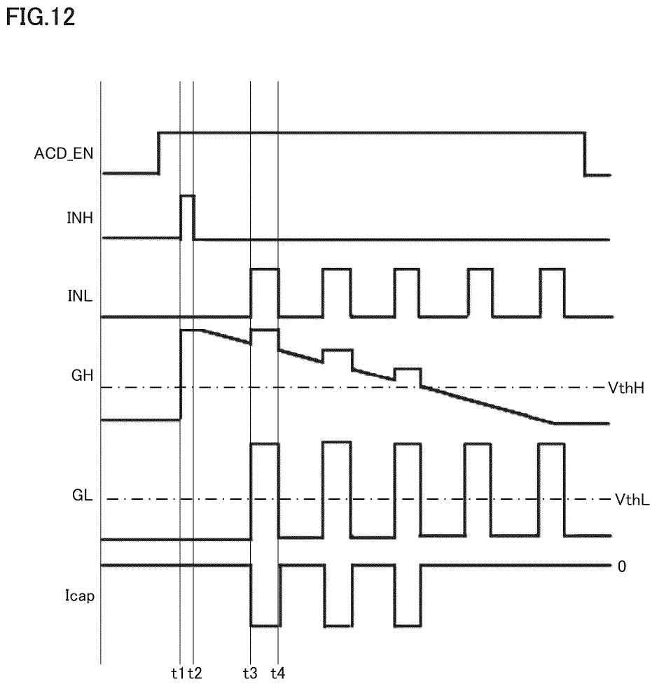

FIG. 12 is a chart showing the active discharge that is performed in the electronic device A of the first embodiment. Sequentially from the top of the chart, the active-discharge control signal ACD_EN, the high-side input pulse signal INH, the low-side input pulse signal INL, the high-side gate drive signal GH, the low-side gate drive signal GL, and discharge current Icap of the capacitor C are shown.

Note that, with regard to the discharge current Icap, a direction from the application terminal for the first supply voltage PVDD to the application terminal for the second supply voltage PVEE via the capacitor C is defined as a positive direction (a direction at the time of charging), and a direction from the application terminal for the second supply voltage PVEE to the application terminal for the first supply voltage PVDD via the capacitor C is defined as a negative direction (a direction at the time of the discharging).

Moreover, dash-dotted lines in the chart respectively indicate respective on-threshold voltages VthH and VthL of the high-side power transistor 2H and the low-side power transistor 2L.

At a time t1, the high-side input pulse signal INH is raised from low level to high level. At this time, the high-side gate drive signal GH rises from low level to high level at the slew rate according to the resistance value of the resistor R11. As a result, the high-side power transistor 2H is subjected to the turn-on without delay.

At a time t2, the high-side input pulse signal INH is caused to fall from high level to low level. At this time, the active-discharge control signal ACD_EN is at high level. Thus, the high-side gate drive signal GH falls from high level to low level mildly at the slew rate according to the resistance value of the resistor R13. As a result, the high-side power transistor 2H is subjected to the mild soft turn-off over a predetermined transition time.

Likewise, at a time t3, at a timing under the state in which the high-side power transistor 2H has been subjected to the soft turn-off, the low-side input pulse signal INL is raised from low level to high level. At this time, the low-side gate drive signal GL rises from low level to high level at the slew rate according to the resistance value of the resistor R21. As a result, the low-side power transistor 2L is subjected to the turn-on without delay.

Moreover, at a time t4, at a timing under the state in which the high-side power transistor 2H has been subjected to the soft turn-off, the low-side input pulse signal INL is caused to fall from high level to low level. At this time, the low-side gate drive signal GL falls from high level to low level at the slew rate according to the resistance value of the resistor R22. As a result, the low-side power transistor 2L is subjected to the turn-off without delay.

In this way, by performing the turn-on of the low-side power transistor 2L at the timing under the state in which the high-side power transistor 2H has been subjected to the soft turn-off, the discharge current Icap of the capacitor C flows through the half-bridge output stage so that the active discharge of the capacitor C is performed. Note that, as shown in the chart, until the discharge current Icap stops flowing through the capacitor C, the low-side power transistor 2L may be repeatedly subjected to the turn-on/turn-off after the time t4.

Incidentally, in the active discharge described above, in response to the turn-on/turn-off of the low-side power transistor 2L, a fluctuation component (dV/dt) is generated in a drain-source voltage Vds (2H) of the high-side power transistor 2H.

At this time, mirror current Im (=Cres×dV/dt) according to the fluctuation component (dV/dt) and to a feedback capacity Cres of the high-side power transistor 2H flows through the gate of the high-side power transistor 2H. Thus, in response to the turn-on/turn-off of the low-side power transistor 2L, a fluctuation component (Im×R13) is generated also in the high-side gate drive signal GH. Moreover, although not shown again, the same applies to a case where the high-side power transistor 2H is subjected to the turn-on at a timing under the state in which the low-side power transistor 2L has been subjected to soft turn-off.

In this way, in the active discharge described above, it is difficult to properly control the discharge current Icap of the capacitor C. Thus, the discharge current Icap that is excessively high can flow through the high-side power transistor 2H and the low-side power transistor 2L. As a precaution, a short-circuit withstand voltage of each of the high-side power transistor 2H and the low-side power transistor 2L needs to be increased.

In the following description, in view of the investigation described above, the second embodiment in which the discharge current Icap of the capacitor C can be controlled is proposed.

### Electronic Device (Second Embodiment)

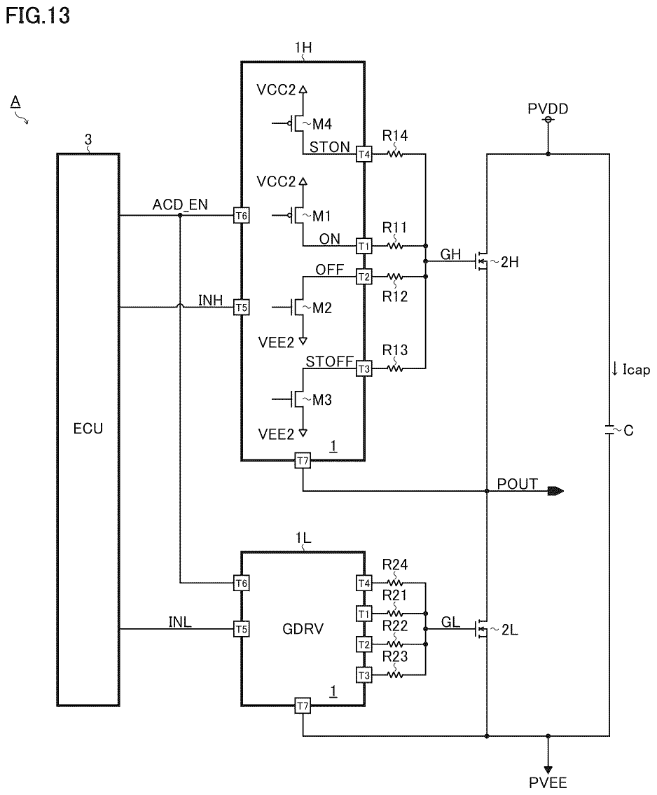

FIG. 13 is a diagram showing the second embodiment of the electronic device A. The electronic device A of this embodiment is basically the same as that of the first embodiment (FIG. 11) described previously except that the semiconductor device 1 further includes transistors M4 (e.g., P-channel MOSFETs) and external terminals T4. Moreover, both the respective external terminals T6 of the high-side gate driver IC 1H and the low-side gate driver IC 1L are connected to the application terminal for the active-discharge control signal ACD_EN.

The transistors M4 establish/block conduction between the application terminals for the positive supply voltage VCC2 and the external terminals T4. A resistor R14 is attached between the external terminal T4 of the high-side gate driver IC 1H and the gate of the high-side power transistor 2H. The resistor R14 has a resistance value higher than that of the resistor R11. A resistor R24 is attached between the external terminal T4 of the low-side gate driver IC 1L and the gate of the low-side power transistor 2L. The resistor R24 has a resistance value higher than that of the resistor R21. The external terminals T4 can be understood as soft turn-on output terminals at the time of the active discharge.

In order to perform soft turn-on of the high-side power transistor 2H at the time of the active discharge, the high-side gate driver IC 1H turns on the transistor M4 and turns off the transistors M1 to M3. At this time, current flows from the application terminal for the positive supply voltage VCC2 to the gate of the high-side power transistor 2H via the transistor M4 and the resistor R14. Thus, the high-side gate drive signal GH, that is, an applied voltage STON to the external terminal T4 rises from low level to high level. As a result, the high-side power transistor 2H is subjected to the soft turn-on. A slew rate of the high-side gate drive signal GH at the time of the soft turn-on can be adjusted according to the resistance value of the resistor R14. Note that, the slew rate at the time of the soft turn-on is lower than the slew rate at the time of the normal turn-on.

The same applies to the low-side gate driver IC 1L. That is, a slew rate of the low-side gate drive signal GL at the time of soft turn-on can be adjusted according to the resistance value of the resistor R24.

Note that, the transistors M1 and M2 can be understood as elements of drive circuits that respectively perform the turn-on or the turn-off of the high-side power transistor 2H and the low-side power transistor 2L at the time of the normal driving (ACD_EN=L). The transistors M3 and M4 can be understood as elements of active discharge circuits that respectively perform the soft turn-on or the soft turn-off of the high-side power transistor 2H and the low-side power transistor 2L at the time of the active discharge (ACD_EN=H) more mildly than the transistors M1 and M2.

The ECU 3 controls both the high-side gate driver IC 1H and the low-side gate driver IC 1L so that, at the time of the active discharge, at a timing under the state in which one of the high-side power transistor 2H and the low-side power transistor 2L has been subjected to the soft turn-off, another one of the high-side power transistor 2H and the low-side power transistor 2L is subjected to the soft turn-on.

### Active Discharge (Second Embodiment)

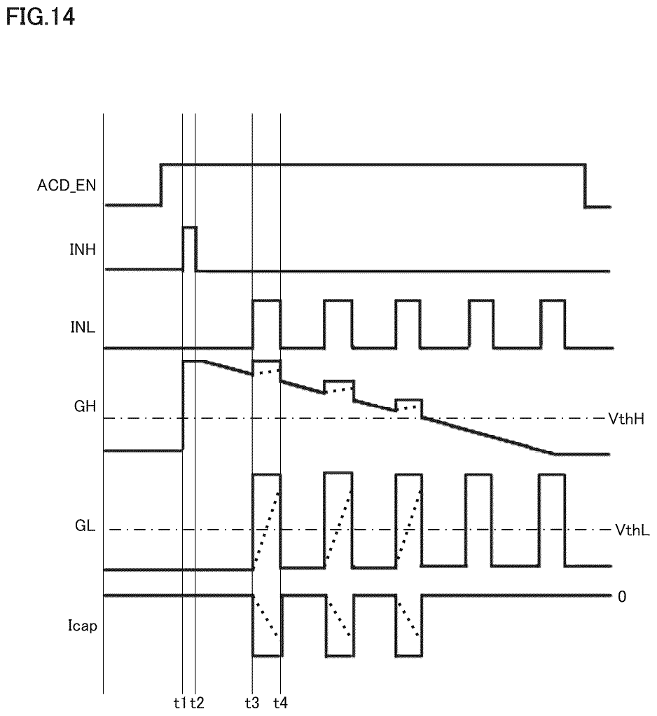

FIG. 14 is a chart showing the active discharge that is performed in the electronic device A of the second embodiment. Sequentially from the top of the chart, as in FIG. 12 referred to previously, the active-discharge control signal ACD_EN, the high-side input pulse signal INH, the low-side input pulse signal INL, the high-side gate drive signal GH, the low-side gate drive signal GL, and the discharge current Icap of the capacitor C are shown.

As described previously referring to FIG. 12, at the time t3, at the timing under the state in which the high-side power transistor 2H has been subjected to the soft turn-off, the low-side input pulse signal INL is raised from low level to high level. At this time, as indicated by the dotted line in the chart, the low-side gate drive signal GL rises from low level to high level at the slew rate according to the resistance value of the resistor R24. As a result, the low-side power transistor 2L is subjected to the mild soft turn-on.

In this way, in the electronic device A of this embodiment, at the timing under the state in which the high-side power transistor 2H has been subjected to the soft turn-off, the low-side power transistor 2L is subjected to the soft turn-on. This configuration helps suppress the fluctuation component (dV/dt) that is generated in the drain-source voltage Vds of the low-side power transistor 2L. Thus, the discharge current Icap at the time of the active discharge can be controlled according to the pulse width of the low-side input pulse signal INL and the slew rate of the low-side gate drive signal GL (i.e., the resistance value of the resistor R24).

Note that, although not shown again, the ECU 3 may control both the high-side gate driver IC 1H and the low-side gate driver IC 1L so that, at the time of the active discharge of the capacitor C, at the timing under the state in which the low-side power transistor 2L has been subjected to the soft turn-off, the high-side power transistor 2H is subjected to the soft turn-on.

Moreover, as a modification, the ECU 3 may control both the high-side gate driver IC 1H and the low-side gate driver IC 1L so that, at the time of the active discharge of the capacitor C, at a timing under the state in which one of the high-side power transistor 2H and the low-side power transistor 2L has been subjected to the soft turn-on, another one of the high-side power transistor 2H and the low-side power transistor 2L is also subjected to the soft turn-on.

### Electronic Device (Third Embodiment)

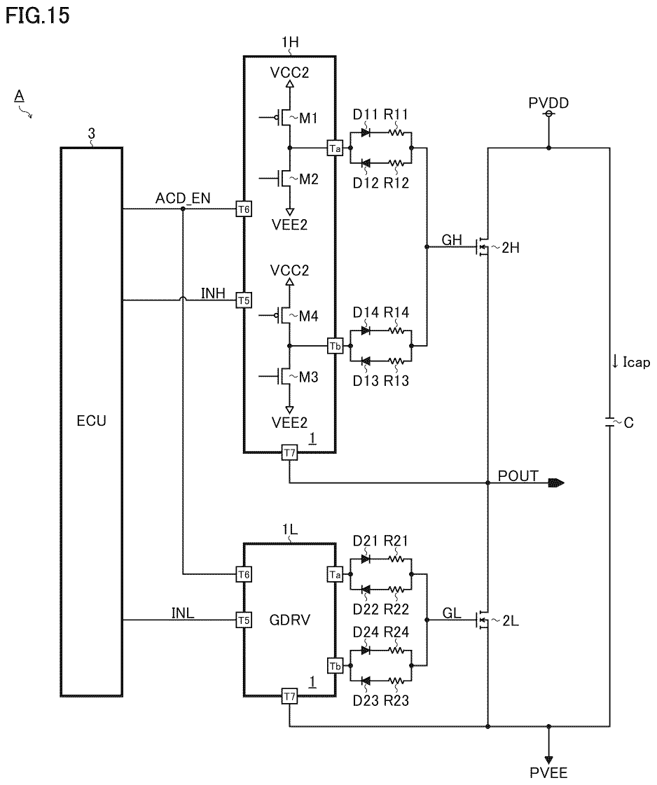

FIG. 15 is a diagram showing the third embodiment of the electronic device A. The electronic device A of this embodiment is basically the same as that of the second embodiment (FIG. 13) described previously except that the external terminals T1 to T4 of the semiconductor device 1 are integrated into external terminals Ta and Tb.

In terms of what is shown in the diagram, the external terminals T1 and T2 described previously are replaced with the external terminals Ta. The external terminals Ta can be understood as turn-on/turn-off output terminals. Likewise, the external terminals T3 and T4 described previously are replaced with the external terminals Tb. The external terminals Tb can be understood as soft turn-on/soft turn-off output terminals.

The transistors M1 establish/block conduction between the application terminals for the positive supply voltage VCC2 and the external terminals Ta. The transistors M2 establish/block conduction between the application terminals for the negative supply voltage VEE2 and the external terminals Ta. The transistors M3 establish/block conduction between the application terminals for the negative supply voltage VEE2 and the external terminals Tb. The transistors M4 establish/block conduction between the application terminals for the positive supply voltage VCC2 and the external terminals Tb.

Moreover, according to such a modification of the output system, diodes D11, D12, D13, and D14 are additionally attached to the high-side gate driver IC 1H. In terms of what is shown in the diagram, the anode of the diode D11 and the cathode of the diode D12 are connected to the external terminal Ta of the high-side gate driver IC 1H. The cathode of the diode D11 is connected to the first terminal of the resistor R11. The anode of the diode D12 is connected to the first terminal of the resistor R12. The second terminals of both the resistors R11 and R12 are connected to the gate of the high-side power transistor 2H.

Moreover, the cathode of the diode D13 and the anode of the diode D14 are connected to the external terminal Tb of the high-side gate driver IC 1H. The anode of the diode D13 is connected to the first terminal of the resistor R13. The cathode of the diode D14 is connected to the first terminal of the resistor R14. The second terminals of both the resistors R13 and R14 are connected to the gate of the high-side power transistor 2H.

The same applies also to the low-side gate driver IC 1L, that is, diodes D21, D22, D23, and D24 are additionally attached to it. In terms of what is shown in the diagram, the anode of the diode D21 and the cathode of the diode D22 are connected to the external terminal Ta of the low-side gate driver IC 1L. The cathode of the diode D21 is connected to the first terminal of the resistor R21. The anode of the diode D22 is connected to the first terminal of the resistor R22. The second terminals of both the resistors R21 and R22 are connected to the gate of the low-side power transistor 2L.

Moreover, the cathode of the diode D23 and the anode of the diode D24 are connected to the external terminal Tb of the low-side gate driver IC 1L. The anode of the diode D23 is connected to the first terminal of the resistor R23. The cathode of the diode D24 is connected to the first terminal of the resistor R24. The second terminals of both the resistors R23 and R24 are connected to the gate of the low-side power transistor 2L.

In response to the turn-on of the high-side power transistor 2H, current flows from the external terminal Ta of the high-side gate driver IC 1H to the gate of the high-side power transistor 2H via the diode D11 and the resistor R11. Likewise, in response to the turn-off of the high-side power transistor 2H, current flows from the gate of the high-side power transistor 2H to the external terminal Ta of the high-side gate driver IC 1H via the resistor R12 and the diode D12.

Likewise, in response to the soft turn-off of the high-side power transistor 2H, current flows from the gate of the high-side power transistor 2H to the external terminal Tb of the high-side gate driver IC 1H via the resistor R13 and the diode D13. Likewise, in response to the soft turn-on of the high-side power transistor 2H, current flows from the external terminal Tb of the high-side gate driver IC 1H to the gate of the high-side power transistor 2H via the diode D14 and the resistor R14.

In response to the turn-on of the low-side power transistor 2L, current flows from the external terminal Ta of the low-side gate driver IC 1L to the gate of the low-side power transistor 2L via the diode D21 and the resistor R21. Likewise, in response to the turn-off of the low-side power transistor 2L, current flows from the gate of the low-side power transistor 2L to the external terminal Ta of the low-side gate driver IC 1L via the resistor R22 and the diode D22.

Likewise, in response to the soft turn-off of the low-side power transistor 2L, current flows from the gate of the low-side power transistor 2L to the external terminal Tb of the low-side gate driver IC 1L via the resistor R23 and the diode D23. Likewise, in response to the soft turn-on of the low-side power transistor 2L, current flows from the external terminal Tb of the low-side gate driver IC 1L to the gate of the low-side power transistor 2L via the diode D24 and the resistor R24.

In this way, the electronic device A of this embodiment helps reduce the number of the external terminals of the semiconductor device 1 to be smaller than that of the second embodiment (FIG. 13) described previously. Thus, the semiconductor device 1 can be made compact and low-cost.

### Electronic Device (Fourth Embodiment)

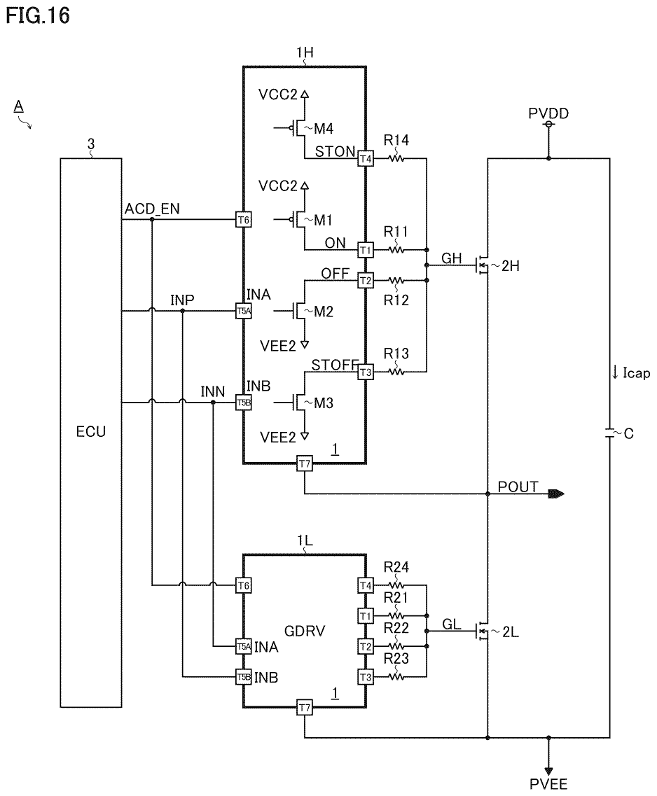

FIG. 16 is a diagram showing the fourth embodiment of the electronic device A. The electronic device A of this embodiment is basically the same as that of the second embodiment (FIG. 13) described previously except that the external terminals T5 of the semiconductor device 1 are changed to external terminals T5A and T5B.

The external terminal T5A of the high-side gate driver IC 1H and the external terminal T5B of the low-side gate driver IC 1L are connected to the application terminal for a positive input pulse signal INP. The external terminal T5B of the high-side gate driver IC 1H and the external terminal T5A of the low-side gate driver IC 1L are connected to the application terminal for a negative input pulse signal INN. The external terminals T5A can be understood as the input terminals for the first input pulse signal INA. The external terminals T5B can be understood as the input terminals for a second input pulse signal INB.

In this way, both the high-side gate driver IC 1H and the low-side gate driver IC 1L accept the first input pulse signal INA and the second input pulse signal INB. The high-side gate driver IC 1H drives the high-side power transistor 2H according to combinations of the logic level of the first input pulse signal INA (corresponding to the positive input pulse signal INP) and the logic level of the second input pulse signal INB (corresponding to the negative input pulse signal INN). Likewise, the low-side gate driver IC 1L drives the low-side power transistor 2L according to combinations of the logic level of the first input pulse signal INA (corresponding to the negative input pulse signal INN) and the logic level of the second input pulse signal INB (corresponding to the positive input pulse signal INP).

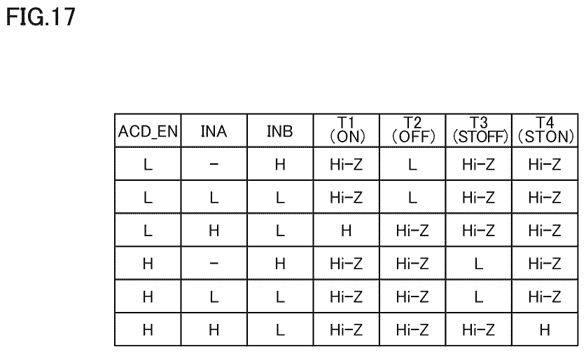

FIG. 17 is a table showing the input/output logic of the semiconductor device 1.

As shown in the first row, the active-discharge control signal ACD_EN is at low level and the second input pulse signal INB is at high level. In this state, irrespective of the logic level of the first input pulse signal INA, the external terminal T2 (OFF) is at low level, and the external terminals T1 (ON), T3 (STOFF), and T4 (STON) are in a high-impedance state.

As shown in the second row, the active-discharge control signal ACD_EN, the first input pulse signal INA, and the second input pulse signal INB are at low level. Also in this state, the external terminal T2 (OFF) is at low level, and the external terminals T1 (ON), T3 (STOFF), and T4 (STON) are in a high-impedance state.

As shown in the third row, the active-discharge control signal ACD_EN and the second input pulse signal INB are at low level, and the first input pulse signal INA is at high level. In this state, the external terminal T1 (ON) is at high level, and the external terminals T2 (OFF), T3 (STOFF), and T4 (STON) are in a high-impedance state.

As shown in the fourth row, the active-discharge control signal ACD_EN and the second input pulse signal INB are at high level. In this state, irrespective of the logic level of the first input pulse signal INA, the external terminal T3 (STOFF) is at low level, and the external terminals T1 (ON), T2 (OFF), and T4 (STON) are in a high-impedance state.

As shown in the fifth row, the active-discharge control signal ACD_EN is at high level, and the first input pulse signal INA and the second input pulse signal INB are at low level. Also in this state, the external terminal T3 (STOFF) is at low level, and the external terminals T1 (ON), T2 (OFF), and T4 (STON) are in a high-impedance state.

As shown in the sixth row, the active-discharge control signal ACD_EN and the first input pulse signal INA are at high level, and the second input pulse signal INB is at low level. In this state, the external terminal T4 (STON) is at low high, and the external terminals T1 (ON), T2 (OFF), and T3 (STOFF) are in a high-impedance state.

### Active Discharge (Fourth Embodiment)

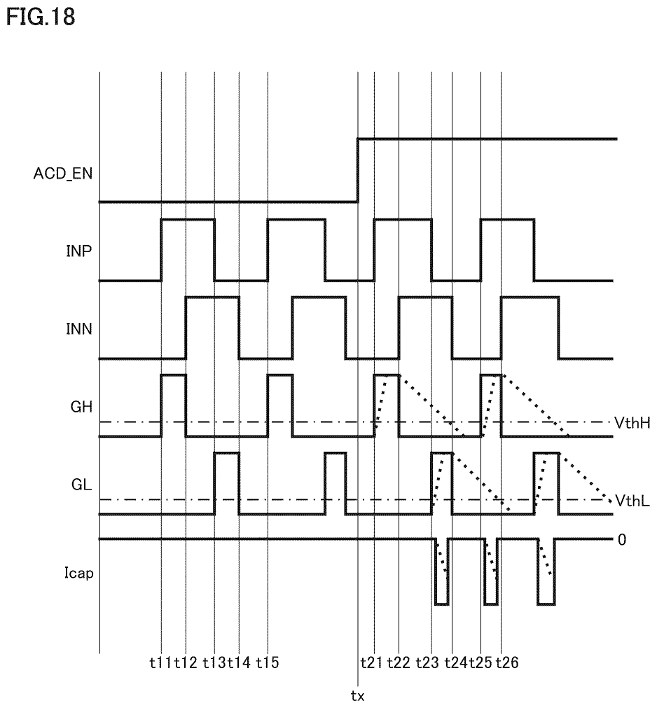

FIG. 18 is a chart showing the active discharge that is performed in the electronic device A of the fourth embodiment. Sequentially from the top of the chart, the active-discharge control signal ACD_EN, the positive input pulse signal INP, the negative input pulse signal INN, the high-side gate drive signal GH, the low-side gate drive signal GL, and the discharge current Icap of the capacitor C are shown.

First, with a focus on the low-level period of the active-discharge control signal ACD_EN (before a time tx), the turn-on/turn-off control at the time of the normal driving will be described.

At a time t11, the respective logic levels of the positive input pulse signal INP and the negative input pulse signal INN are switched from a first input state (INP=L and INN=L) to a second input state (INP=H and INN=L). At this time, the high-side gate driver IC 1H causes the external terminal T1 to be at high level and causes the external terminals T2 to T4 to be in a high-impedance state. Thus, the high-side gate drive signal GH rises to high level at the slew rate according to the resistance value of the resistor R11. As a result, the high-side power transistor 2H is subjected to the turn-on. Likewise, the low-side gate driver IC 1L maintains the external terminal T2 at low level, and maintains the external terminals T1, T3, and T4 in a high-impedance state. Thus, the low-side gate drive signal GL is maintained at low level. As a result, the low-side power transistor 2L is maintained to be off.

At a time t12, the respective logic levels of the positive input pulse signal INP and the negative input pulse signal INN are switched from the second input state (INP=H and INN=L) to a third input state (INP=H and INN=H). At this time, the high-side gate driver IC 1H causes the external terminal T2 to be at low level, and causes the external terminals T1, T3, and T4 to be in a high-impedance state. Thus, the high-side gate drive signal GH falls to low level at the slew rate according to the resistance value of the resistor R12. As a result, the high-side power transistor 2H is subjected to the turn-off. Likewise, the low-side gate driver IC 1L maintains the external terminal T2 at low level, and maintains the external terminals T1, T3, and T4 in a high-impedance state. Thus, the low-side gate drive signal GL is maintained at low level. As a result, the low-side power transistor 2L is maintained to be off.

At a time t13, the respective logic levels of the positive input pulse signal INP and the negative input pulse signal INN are switched from the third input state (INP=H and INN=H) to a fourth input state (INP=L and INN=H). At this time, the high-side gate driver IC 1H maintains the external terminal T2 at low level, and maintains the external terminals T1, T3, and T4 in a high-impedance state. Thus, the high-side gate drive signal GH is maintained at low level. As a result, the high-side power transistor 2H is maintained to be off. Likewise, the low-side gate driver IC 1L causes the external terminal T1 to be at high level and causes the external terminals T2 to T4 to be in a high-impedance state. Thus, the low-side gate drive signal GL rises to high level at the slew rate according to the resistance value of the resistor R21. As a result, the low-side power transistor 2L is subjected to the turn-on.

At a time t14, the respective logic levels of the positive input pulse signal INP and the negative input pulse signal INN are switched from the fourth input state (INP=L and INN=H) to the first input state (INP=L and INN=L). At this time, the high-side gate driver IC 1H maintains the external terminal T2 at low level, and maintains the external terminals T1, T3, and T4 in a high-impedance state. Thus, the high-side gate drive signal GH is maintained at low level. As a result, the high-side power transistor 2H is maintained to be off. Likewise, the low-side gate driver IC 1L causes the external terminal T2 to be at low level, and causes the external terminals T1, T3, and T4 to be in a high-impedance state. Thus, the low-side gate drive signal GL falls to low level at the slew rate according to the resistance value of the resistor R22. As a result, the low-side power transistor 2L is subjected to the turn-off.

Also at or after a time t15, the turn-on/turn-off control as described above is repeated. In particular, in the turn-on/turn-off control of this embodiment, periods what is generally called dead times (the times t12 to t13 and the times t14 to t15) in which both the high-side power transistor 2H and the low-side power transistor 2L are turned off together are provided.

Next, with a focus on the high-level period of the active-discharge control signal ACD_EN (at or after the time tx), the soft turn-on/soft turn-off control at the time of the active discharge will be described.

At a time t21, the respective logic levels of the positive input pulse signal INP and the negative input pulse signal INN are switched from the first input state (INP=L and INN=L) to the second input state (INP=H and INN=L). At this time, the high-side gate driver IC 1H causes the external terminal T4 to be at high level and causes the external terminals T1 to T3 to be in a high-impedance state. Thus, the high-side gate drive signal GH starts to mildly rise at the slew rate according to the resistance value of the resistor R14 (refer to the dotted line of GH). As a result, the high-side power transistor 2H is subjected to the soft turn-on. Likewise, the low-side gate driver IC 1L maintains the external terminal T3 at low level, and maintains the external terminals T1, T2, and T4 in a high-impedance state. Thus, the low-side gate drive signal GL is maintained at low level. As a result, the low-side power transistor 2L is maintained to be off.

At a time t22, the respective logic levels of the positive input pulse signal INP and the negative input pulse signal INN are switched from the second input state (INP=H and INN=L) to the third input state (INP=H and INN=H). At this time, the high-side gate driver IC 1H causes the external terminal T3 to be at low level, and causes the external terminals T1, T2, and T4 to be in a high-impedance state. Thus, the high-side gate drive signal GH starts to mildly fall at the slew rate according to the resistance value of the resistor R13 (refer to the dotted line of GH). As a result, the high-side power transistor 2H is subjected to the soft turn-off. Likewise, the low-side gate driver IC 1L maintains the external terminal T2 at low level, and maintains the external terminals T1, T3, and T4 in a high-impedance state. Thus, the low-side gate drive signal GL is maintained at low level. As a result, the low-side power transistor 2L is maintained to be off.

At a time t23, the respective logic levels of the positive input pulse signal INP and the negative input pulse signal INN are switched from the third input state (INP=H and INN=H) to the fourth input state (INP=L and INN=H). At this time, the high-side gate driver IC 1H maintains the external terminal T3 at low level, and maintains the external terminals T1, T2, and T4 in a high-impedance state. Thus, the high-side gate drive signal GH continues to mildly fall at the slew rate according to the resistance value of the resistor R13 (refer to the dotted line of GH). As a result, the high-side power transistor 2H continues to be subjected to the soft turn-off. Likewise, the low-side gate driver IC 1L causes the external terminal T4 to be at high level and causes the external terminals T1 to T3 to be in a high-impedance state. Thus, the low-side gate drive signal GL starts to mildly rise at the slew rate according to the resistance value of the resistor R24 (refer to the dotted line of GL). As a result, the low-side power transistor 2L is subjected to the soft turn-on.

At this time, the discharge current Icap of the capacitor C flows via the high-side power transistor 2H and the low-side power transistor 2L. The discharge current Icap can be controlled according to the pulse width of the negative input pulse signal INN and to the respective slew rates of the high-side gate drive signal GH and the low-side gate drive signal GL (i.e., the resistance values of the resistors R14 and R24). Note that, the discharge current Icap continues to flow until the high-side gate drive signal GH falls below the on-threshold voltage VthH of the high-side power transistor 2H after the low-side gate drive signal GL has exceeded the on-threshold voltage VthL of the low-side power transistor 2L.

At a time t24, the respective logic levels of the positive input pulse signal INP and the negative input pulse signal INN are switched from the fourth input state (INP=L and INN=H) to the first input state (INP=L and INN=L). At this time, the high-side gate driver IC 1H maintains the external terminal T3 at low level, and maintains the external terminals T1, T2, and T4 in a high-impedance state. Thus, the high-side gate drive signal GH continues to mildly fall to low level at the slew rate according to the resistance value of the resistor R13. As a result, the soft turn-off of the high-side power transistor 2H is completed. Likewise, the low-side gate driver IC 1L causes the external terminal T3 to be at low level, and causes the external terminals T1, T2, and T4 to be in a high-impedance state. Thus, the low-side gate drive signal GL starts to mildly fall at the slew rate according to the resistance value of the resistor R23 (refer to the dotted line of GL). As a result, the low-side power transistor 2L is subjected to the soft turn-off.

At a time t25, the respective logic levels of the positive input pulse signal INP and the negative input pulse signal INN are switched from the first input state (INP=L and INN=L) to the second input state (INP=H and INN=L). At this time, the high-side gate driver IC 1H causes the external terminal T4 to be at high level and causes the external terminals T1 to T3 to be in a high-impedance state. Thus, the high-side gate drive signal GH starts to mildly rise at the slew rate according to the resistance value of the resistor R14 (refer to the dotted line of GH). As a result, the high-side power transistor 2H is subjected to the soft turn-on. Likewise, the low-side gate driver IC 1L maintains the external terminal T3 at low level, and maintains the external terminals T1, T2, and T4 in a high-impedance state. Thus, the low-side gate drive signal GL continues to mildly fall at the slew rate according to the resistance value of the resistor R23 (refer to the dotted line of GL). As a result, the low-side power transistor 2L continues to be subjected to the soft turn-off.

At this time, the discharge current Icap of the capacitor C flows via the high-side power transistor 2H and the low-side power transistor 2L. The discharge current Icap can be controlled according to the pulse width of the positive input pulse signal INP and to the respective slew rates of the high-side gate drive signal GH and the low-side gate drive signal GL (i.e., the resistance values of the resistors R14 and R24). Note that, the discharge current Icap continues to flow until the low-side gate drive signal GL falls below the on-threshold voltage VthL of the low-side power transistor 2L after the high-side gate drive signal GH has exceeded the on-threshold voltage VthH of the high-side power transistor 2H.

Also at or after a time t26, the soft turn-on/soft turn-off control as described above is repeated. In particular, in the soft turn-on/soft turn-off control of this embodiment, periods what is generally called dead times (the times t22 to t23 and the times t24 to t25) in which both the high-side power transistor 2H and the low-side power transistor 2L are turned off together are provided.

In this way, the electronic device A of this embodiment helps proper active-discharge control while providing the dead times in which both the high-side power transistor 2H and the low-side power transistor 2L are turned off.

### Semiconductor Device

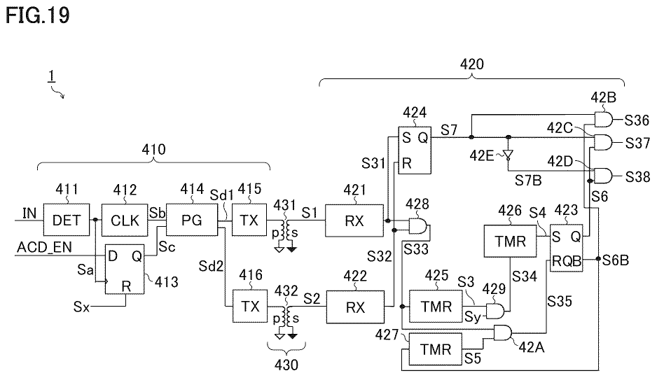

FIG. 19 is a diagram showing a configuration example of the semiconductor device 1. The semiconductor device 1 of this configuration example includes a first chip 410, a second chip 420, and a third chip 430. The first chip 410, the second chip 420, and the third chip 430 may be sealed in a single package.

Note that, similar to the signal transmission device 200 (FIG. 1) described previously, the semiconductor device 1 may be a semiconductor integrated circuit device (what is generally called an isolated gate driver IC) that, while isolating between input and output, generates, in the second chip 420, the output pulse signal OUT according to the input pulse signal IN to be input to the first chip 410, and drives an unillustrated switching device.

In that case, the first chip 410 corresponds to the controller chip 210 described previously. Further, the second chip 420 corresponds to the driver chip 220 described previously. Still further, the third chip 430 corresponds to the transformer chip 230 described previously.

An edge detection circuit 411, an oscillator circuit 412, a D flip-flop 413, a pulse generating circuit 414, and transmission circuits 415 and 416 are integrated in the first chip 410.

Reception circuits 421 and 422, RS flip-flops 423 and 424, timers 425, 426, and 427, AND gates 428, 429, 42A, 42B, 42C, and 42D, and an inverter 42E are integrated in the second chip 420. Moreover, although not shown in the diagram, the transistors M1 to M4 described previously are also integrated in the second chip 420.

Transformers 431 and 432 (corresponding respectively to a first insulation device and a second insulation device) are integrated in the third chip 430. Note that, the transformer 431 includes a primary coil 431p and a secondary coil 431s. Likewise, the transformer 432 includes a primary coil 432p and a secondary coil 432s.

The edge detection circuit 411 detects both the rising edge and the falling edge of the input pulse signal IN, and outputs an edge detection signal Sa. The edge detection circuit 411 may include an input filter for removing noise components that are superimposed on the input pulse signal IN. For example, after a lapse of a predetermined mask time (e.g., 50 ns) since the detection of both the rising edge and the falling edge of the input pulse signal IN, the edge detection circuit 411 may generate a single low-level pulse in the edge detection signal Sa. The input pulse signal IN may be, for example, the first input pulse signal INA described previously (FIG. 16).

The oscillator circuit 412 generates a drive clock signal Sb for the pulse generating circuit 414 in response to the edge detection signal Sa.

The D flip-flop 413 latches, by being triggered by the edge detection signal Sa to be input to its clock input terminal (>), the active-discharge control signal ACD_EN to be input to its data input terminal (D), and outputs a latch output signal Sc from its output terminal (Q). That is, the logic level of the active-discharge control signal ACD_EN is reflected in the pulse generation after the detection of the edge of the input pulse signal IN. Note that, the D flip-flop 413 resets the logic level of the latch output signal Sc to its default value (e.g., low level) under a state in which a fault clear signal Sx that is input to its reset terminal (R) has reached a logic level at the time of fault clearing.

The pulse generating circuit 414 generates both transmission pulse signals Sd1 and Sd2 in response to the drive clock signal Sb and the latch output signal Sc. For example, under the state in which the latch output signal Sc is at low level, the pulse generating circuit 414 generates the transmission pulse signal Sd1 or Sd2 in a drive cycle TX (e.g., 100 ns). Likewise, under the state in which the latch output signal Sc is at high level, the pulse generating circuit 414 continues to generate a pulse signal in a drive cycle TY (e.g., 25 ns) over a duration TZ (e.g., 0.5 μs).

Note that, the second chip 420 distinguishes between the normal driving (ACD_EN=L) and the active discharge (ACD=H) according to whether the transformer 431 or 432 is pulse-driven in the drive cycle TX or pulse-driven in the drive cycle TY. This will be described in detail below.

The transmission circuit 415 pulse-drives the primary coil 431p of the transformer 431 in response to the transmission pulse signal Sd1.

The transmission circuit 416 pulse-drives the primary coil 432p of the transformer 432 in response to the transmission pulse signal Sd2.

The reception circuit 421 outputs a reception pulse signal S31 in response to a reception pulse signal S1 from the secondary coil 431s of the transformer 431.

The reception circuit 422 outputs a reception pulse signal S32 in response to a reception pulse signal S2 from the secondary coil 432s of the transformer 432.

The RS flip-flop 423 switches the respective logic levels of a latch output signal S6 to be output from its output terminal (Q) and an inverted latch output signal S6B to be output from its inverting output terminal (QB) according to a timer output signal S4 to be input to its set terminal(S) and an AND signal S35 to be input to its reset terminal (R). For example, the RS flip-flop 423 sets the latch output signal S6 to high level and sets the inverted latch output signal S6B to low level according to the timer output signal S4. Likewise, the RS flip-flop 423 resets the latch output signal S6 to low level and resets the inverted latch output signal S6B to high level according to the AND signal S35.

The RS flip-flop 424 switches the logic level of a latch output signal S7 to be output from its output terminal (Q) according to the reception pulse signal S31 to be input to its set terminal(S) and the reception pulse signal S32 to be input to its reset terminal (R). For example, the RS flip-flop 424 sets the latch output signal S7 to high level according to the reception pulse signal S31. Likewise, the RS flip-flop 424 resets the latch output signal S7 to low level according to the reception pulse signal S31.

The timer 425 outputs a timer output signal S3 in response to an AND signal S33. For example, the timer output signal S3 is at high level in response to generating of a pulse in the AND signal S33. Moreover, the timer output signal S3 is at low level under a state in which the pulse has not been generated to the AND signal S33 over a predetermined timer time Tx. Note that, the timer time Tx is shorter than the drive cycle TX (e.g., 100 ns) and longer than the drive cycle TY (e.g., 25 ns) described previously. The timer time Tx may be, for example, 40 ns.

The timer 426 outputs the timer output signal S4 in response to an AND signal S34. For example, the timer output signal S4 is at high level under a state in which the AND signal S34 has been maintained at high level over a predetermined timer time Ty. Moreover, the timer output signal S4 falls to low level without delay in response to falling of the AND signal S34 to low level. The timer time Ty may be, for example, 200 ns. Note that, the AND signal S34 can be understood as a reset signal for the timer 426.

The timer 427 outputs a timer output signal S5 in response to the inverted latch output signal S6B. For example, the timer output signal S5 is maintained at high level over a predetermined timer time Tz after the inverted latch output signal S6B has fallen to low level. The timer time Tz may be, for example, 0.8 μs.

The AND gate 428 outputs the AND signal S33 in response to the reception pulse signals S31 and S32. The AND signal S33 is at low level under a state in which at least one of the reception pulse signals S31 and S32 is at low level. The AND signal S33 is at high level under a state in which both the reception pulse signals S31 and S32 are at high level.

The AND gate 429 outputs the AND signal S34 in response to the timer output signal S3 and an UVLO [under voltage lock out] signal Sy. The AND signal S34 is at low level under a state in which at least one of the timer output signal S3 and the UVLO signal Sy is at low level. The AND signal S34 is at high level under a state in which both the timer output signal S3 and the UVLO signal Sy are at high level. The UVLO signal Sy is at low level under a state in which UVLO has been detected, and at high level under a state in which UVLO has been cleared.

The AND gate 42A outputs the AND signal S35 in response to the AND signal S33 and the timer output signal S5. The AND signal S35 is at low level under a state in which at least one of the AND signal S33 and the timer output signal S5 is at low level. The AND signal S35 is at high level under a state in which both the AND signal S33 and the timer output signal S5 are at high level.

The AND gate 42B outputs an AND signal S36 in response to the inverted latch output signal S6B and the latch output signal S7. The AND signal S36 is at low level under a state in which at least one of the inverted latch output signal S6B and the latch output signal S7 is at low level. The AND signal S36 is at high level under a state in which both the inverted latch output signal S6B and the latch output signal S7 are at high level.

For example, under the state in which the AND signal S36 is at high level, the transistor M1 described previously is turned on. Likewise, under the state in which the AND signal S36 is at low level, the transistor M2 described previously is turned on. That is, the AND signal S36 functions as the control signal for the drive circuit that performs turn-on or turn-off of the switching device (high-side power transistor 2H or low-side power transistor 2L) to be driven. Thus, circuit elements relating to generation of the AND signal S36, that is, the RS flip-flop 424 and the AND gate 42B can be understood as elements of the drive circuit as well as the transistors M1 and M2 described previously.

The AND gate 42C outputs an AND signal S37 in response to the latch output signals S6 and S7. The AND signal S37 is at low level under a state in which at least one of the latch output signals S6 and S7 is at low level. The AND signal S37 is at high level under a state in which both the latch output signals S6 and S7 are at high level.

The AND gate 42D outputs an AND signal S38 in response to the latch output signal S6 and an inverted latch output signal S7B. The AND signal S38 is at low level under a state in which at least one of the latch output signal S6 and the inverted latch output signal S7B is at low level. The AND signal S38 is at high level under a state in which both the latch output signal S6 and the inverted latch output signal S7B are at high level.

For example, under the state in which the AND signal S37 is at high level, the transistor M3 described previously is turned on. Likewise, under the state in which the AND signal S37 is at low level, the transistor M3 described previously is turned off. Moreover, under the state in which the AND signal S38 is at high level, the transistor M4 described previously is turned on. Likewise, under the state in which the AND signal S38 is at low level, the transistor M4 described previously is turned off.

That is, the AND signals S37 and S38 function as the control signal for the active discharge circuit that performs soft turn-on or soft turn-off the switching device (high-side power transistor 2H or low-side power transistor 2L) to be driven. Thus, circuit elements relating to generation of both the AND signals S37 and S38, that is, the RS flip-flops 423 and 424, the timers 425 to 427, the AND gates 428 to 42A, 42C, and 42D, and the inverter 42E can be understood as elements of the active discharge circuit as well as the transistors M3 and M4 described previously.

The inverter 42E generates the inverted latch output signal S7B by inverting the logic level of the latch output signal S7. Thus, under the state in which the latch output signal S7 is at high level, the inverted latch output signal S7B is at low level. Likewise, under the state in which the latch output signal S7 is at low level, the inverted latch output signal S7B is at high level.

The transformer 431 transmits, while isolating between the transmission circuit 415 and the reception circuit 421, the transmission pulse signal Sd1 as the reception pulse signal S1.

The transformer 432 transmits, while isolating between the transmission circuit 416 and the reception circuit 422, the transmission pulse signal Sd2 as the reception pulse signal S2.

The semiconductor device 1 of this configuration example helps, by using the transformers 431 and 432, perform not only the turn-on control and the turn-off control at the time of the normal driving, but also the soft turn-on control and the soft turn-off control at the time of the active discharge. Note that, if an increase in the number of the transformers to be integrated in the third chip 430 is allowable, transformers dedicated respectively to the soft turn-on control and the soft turn-off control may be used.

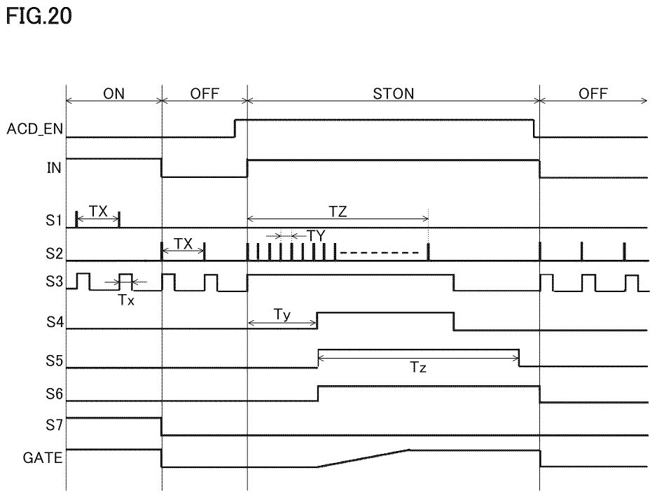

FIG. 20 is a chart showing an example of the soft turn-on control in the semiconductor device 1. Sequentially from the top of the chart, the active-discharge control signal ACD_EN, the input pulse signal IN, the reception pulse signals S1 and S2, the timer output signals S3 to S5, the latch output signals S6 and S7, and a gate drive signal GATE are shown. For example, the input pulse signal IN can be understood as the first input pulse signal INA described previously. Moreover, the gate drive signal GATE can be understood as the high-side gate drive signal GH or the low-side gate drive signal GL described previously.

First, with a focus on the low-level period of the active-discharge control signal ACD_EN, the turn-on/turn-off control at the time of the normal driving will be described.

In the low level period of the active-discharge control signal ACD_EN, under the state in which the input pulse signal IN is at high level, the reception pulse signal S1 is driven in the drive cycle TX (e.g., 100 ns). In this way, the first chip 410 indicates that the input pulse signal IN is at high level to the second chip 420 via the transformer 431. Note that, high level of the input pulse signal IN can be understood as a logic level for turning on the switching device (high-side power transistor 2H or low-side power transistor 2L) to be driven.

Likewise, under the state in which the input pulse signal IN is at low level, the reception pulse signal S2 is driven in the drive cycle TX. In this way, the first chip 410 indicates that the input pulse signal IN is at low level to the second chip 420 via the transformer 432. Note that, low level of the input pulse signal IN can be understood as a logic level for turning off the switching device (high-side power transistor 2H or low-side power transistor 2L) to be driven.

The timer output signal S3 rises to high level every time a pulse is generated in one of the reception pulse signals S1 and S2. Note that, the timer output signal S3 falls to low level again after the timer time Tx has elapsed with the pulse having been generated neither in the reception pulse signal S1 nor S2. In this way, at the time of the normal driving, the timer output signal S3 periodically falls to low level. Thus, the timer output signal S4 is maintained at low level. As a result, the timer output signal S5 and the latch output signal S6 remain at low level.

Under the state in which the latch output signal S6 is at low level, the latch output signal S7 is through-output as the unillustrated AND signal S36, and the unillustrated AND signals S37 and S38 are held at low level.

In the state described above, for example, in response to the pulse-driving of the reception pulse signal S1 under the state in which the input pulse signal IN is at high level, the latch output signal S7, that is, the unillustrated AND signal S36 is set to high level. Thus, the transistor M1 is turned on, and the gate drive signal GATE is raised to high level.

Likewise, in response to the pulse-driving of the reception pulse signal S2 under the state in which the input pulse signal IN is at low level, the latch output signal S7, that is, the unillustrated AND signal S36 is reset to low level. Thus, the transistor M2 is turned on, and the gate drive signal GATE is caused to fall to low level.

In this way, in the low level period of the active-discharge control signal ACD_EN, the turn-on/turn-off control of the high-side power transistor 2H or the low-side power transistor 2L is performed by the transistors M1 and M2.

Next, with a focus on the high-level period of the active-discharge control signal ACD_EN, the soft turn-on control at the time of the active discharge will be described.

In the high-level period of the active-discharge control signal ACD_EN, in response to the raising of the input pulse signal IN from low level to high level, the reception pulse signal S2 is driven in the drive cycle TY (e.g., 25 ns) over the duration TZ (e.g., 0.5 μs).

The timer output signal S3 rises to high level in response to the pulse-driving of the reception pulse signal S2. Note that, the reception pulse signal S2 is pulse-driven in the drive cycle TY shorter than the timer time Tx (e.g., 40 ns). Thus, the timer output signal S3 is maintained at high level without being periodically reset to low level.

The timer output signal S4 is at high level under the state in which the timer output signal S3, that is, the unillustrated AND signal S34 has been maintained at high level over the timer time Ty (e.g., 200 ns). As a result, the latch output signal S6 is set to high level. Moreover, the timer output signal S5 is maintained at high level over the timer time Tz (e.g., 0.8 μs) after the latch output signal S6 has risen to high level. Note that, in the high level period of the timer output signal S5, the reset operation by the RS flip-flop 423 in response to the reception pulse signals S1 and S2, that is, the unillustrated AND signal S33, is masked.

Under the state in which the latch output signal S6 is at high level, while the unillustrated AND signal S36 is held at low level, the latch output signal S7 and the unillustrated inverted latch output signal S7B are through-output respectively as the unillustrated AND signals S37 and S38.

In terms of what is shown in the chart, under the state in which the reception pulse signal S2 has been pulse-driven in response to the transition to high level of the input pulse signal IN, the latch output signal S7 is at low level, and hence the unillustrated AND signal S38 is at high level. Thus, the transistor M4 is turned on, and the gate drive signal GATE is relatively mildly raised to high level. That is, the soft turn-on control of the high-side power transistor 2H or the low-side power transistor 2L is performed by the transistor M4.

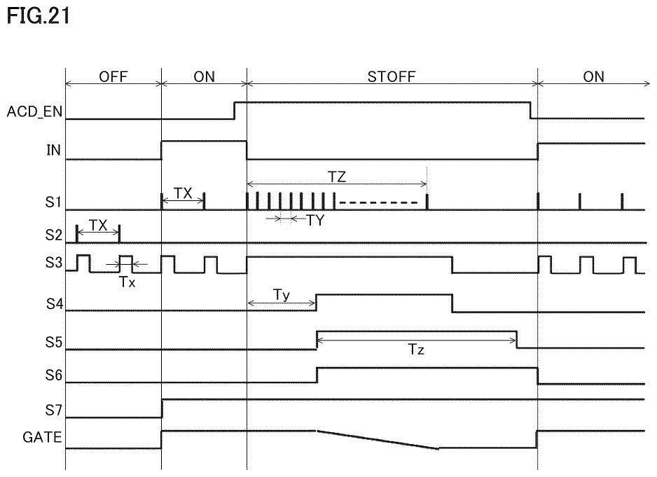

FIG. 21 is a chart showing an example of the soft turn-off control in the semiconductor device 1. As in FIG. 20 referred to previously, sequentially from the top of the chart, the active-discharge control signal ACD_EN, the input pulse signal IN, the reception pulse signals S1 and S2, the timer output signals S3 to S5, the latch output signals S6 and S7, and the gate drive signal GATE are shown.

The low-level period of the active-discharge control signal ACD_EN is the same as that shown in FIG. 20 referred to previously. In the following description, with a focus on the high-level period of the active-discharge control signal ACD_EN, the soft turn-off control at the time of the active discharge will be described.

In the high-level period of the active-discharge control signal ACD_EN, in response to the falling of the input pulse signal IN from high level to low level, the reception pulse signal S1 is driven in the drive cycle TY (e.g., 25 ns) over the duration TZ (e.g., 0.5 μs).

The timer output signal S3 rises to high level in response to the pulse-driving of the reception pulse signal S1. Note that, the reception pulse signal S1 is pulse-driven in the drive cycle TY shorter than the timer time Tx (e.g., 40 ns). Thus, as shown also in FIG. 20 referred to previously, the timer output signal S3 is maintained at high level without being periodically reset to low level.

The timer output signal S4 is at high level under the state in which the timer output signal S3, that is, the unillustrated AND signal S34 has been maintained at high level over the timer time Ty (e.g., 200 ns). As a result, the latch output signal S6 is set to high level. Moreover, the timer output signal S5 is maintained at high level over the timer time Tz (e.g., 0.8 μs) after the latch output signal S6 has risen to high level. Note that, exactly as shown also in FIG. 20 referred to previously, in the high level period of the timer output signal S5, the reset operation by the RS flip-flop 423 in response to the reception pulse signals S1 and S2, that is, the unillustrated AND signal S33, is masked.

Under the state in which the latch output signal S6 is at high level, while the unillustrated AND signal S36 is held at low level, the latch output signal S7 and the unillustrated inverted latch output signal S7B are through-output respectively as the unillustrated AND signals S37 and S38.

In terms of what is shown in the chart, under the state in which the reception pulse signal S1 has been pulse-driven in response to the transition to low level of the input pulse signal IN, the latch output signal S7 is at high level, and hence the unillustrated AND signal S37 is at high level. Thus, the transistor M3 is turned on, and the gate drive signal GATE is caused to relatively mildly fall to low level. That is, the soft turn-off control of the high-side power transistor 2H or the low-side power transistor 2L is performed by the transistor M3.

### Application to Vehicle

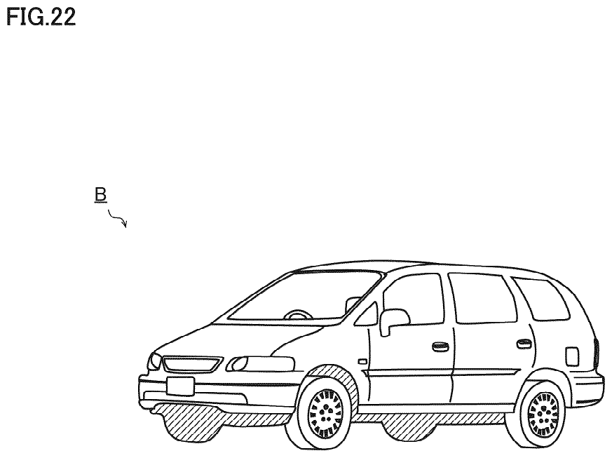

FIG. 22 is an exterior view of a vehicle. The vehicle B of this configuration example incorporates various electronic devices that operates by being supplied with power from a battery.

The vehicle B may be an engine vehicle or may be an electric vehicle (an xEV such as a BEV [battery electric vehicle], an HEV [hybrid electric vehicle], a PHEV/PHV [plug-in hybrid electric vehicle/plug-in hybrid vehicle], or an FCEV/FCV [fuel cell electric vehicle/fuel cell vehicle]).

Note that, the signal transmission device 200 and the semiconductor devices 1, 1H, and 1L described previously may be installed in any of the electronic devices to be incorporated in the vehicle B.

### Appendices

According to the present disclosure, it is possible to properly control discharge current that flows at the time of active discharge. In the following description, appendices of the present disclosure are provided.

### Appendix 1

A semiconductor device (1, 1H, 1L), including:
a drive circuit (M1, M2) configured to perform one of turn-on and turn-off of a switching device (2H, 2L) to be driven at a time of normal driving (ACD_EN=L); and
an active discharge circuit (M3, M4) configured to perform one of soft turn-on and soft turn-off of the switching device (2H, 2L) more mildly than the one of the turn-on and the turn-off by the drive circuit (M1, M2) at a time of active discharge (ACD_EN=H).

### Appendix 2

The semiconductor device (1, 1H, 1L) according to Appendix 1, in which
the drive circuit (M1, M2) includes
   a first transistor (M1) configured to perform one of establishment and blocking of conduction between an application terminal for a first voltage (VCC2) and a first external terminal (T1), and
   a second transistor (M2) configured to perform one of establishment and blocking of conduction between an application terminal for a second voltage (VEE2) and a second external terminal (T2),
the active discharge circuit (M3, M4) includes
   a third transistor (M3) configured to perform one of establishment and blocking of conduction between the application terminal for the second voltage (VEE2) and a third external terminal (T3), and
   a fourth transistor (M4) configured to perform one of establishment and blocking of conduction between the application terminal for the first voltage (VCC2) and a fourth external terminal (T4).

### Appendix 3

The semiconductor device (1, 1H, 1L) according to Appendix 2, in which
   the first external terminal (T1) and the second external terminal (T2) are the same external terminal (Ta), and
   the third external terminal (T3) and the fourth external terminal (T4) are the same external terminal (Tb).

### Appendix 4

The semiconductor device (1, 1H, 1L) according to any of Appendices 1 to 3, in which the semiconductor device (1, 1H, 1L)
   accepts a first input pulse signal (INP) and a second input pulse signal (INN), and
   drives the switching device (2H, 2L) according to combinations of respective logic levels of the first input pulse signal (INP) and the second input pulse signal (INN).

### Appendix 5

The semiconductor device (1, 1H, 1L) according to any of Appendices 1 to 4, further including:
   a first chip (410) configured to allow an input pulse signal (IN) to be input to the first chip (410);
   a second chip (420) in which the drive circuit (M1, M2) and the active discharge circuit (M3, M4) are integrated; and
   a third chip (430) in which a first insulation device (431) and a second insulation device (432) are integrated, in which
   the first chip (410)
indicates, to the second chip (420) via the first insulation device (431), that the input pulse signal (IN) is at a logic level for turning on the switching device (2H, 2L), and
indicates, to the second chip (420) via the second insulation device (432), that the input pulse signal (IN) is at a logic level for turning off the switching device (2H, 2L).

### Appendix 6

The semiconductor device (1, 1H, 1L) according to appendix 5, in which
the first chip (410) drives
   one of the first insulation device (431) and the second insulation device (432) in a first drive cycle (TY) at the time of the normal driving (ACD_EN=L), and drives
   one of the first insulation device (431) and the second insulation device (432) in a second drive cycle (TY) at the time of the active discharge (ACD_EN=H), and
the second chip (420) distinguishes between the normal driving (ACD_EN=L) and the active discharge (ACD_EN=H) according to a corresponding one of the first drive cycle (TX) and the second drive cycle (TY) of one of the first insulation device (431) and the second insulation device (432).

### Appendix 7

An electronic device (A), including:
   a first switching device (2H) and a second switching device (2L) that form a half-bridge output stage by being connected in series between an application terminal for a first supply voltage (PVDD) and an application terminal for a second supply voltage (PVEE);
   a capacitor (C) connected in parallel to the half-bridge output stage between the application terminal for the first supply voltage (PVDD) and the application terminal for the second supply voltage (PVEE);
   a first driving device (1H) configured to drive the first switching device (2H);
   a second driving device (1L) configured to drive the second switching device (2L); and
   a control device (3) configured to control the first driving device (1H) and the second driving device (1L), in which
   the first driving device (1H) and the second driving device (1L) are each the semiconductor device (1, 1H, 1L) according to any of Appendices 1 to 6.

### Appendix 8

The electronic device (A) according to Appendix 7, in which
   the control device (3) controls both the first driving device (1H) and the second driving device (1L) so that, at a timing under a state in which one of the first switching device (2H) and the second switching device (2L) has been subjected to the soft turn-off, another one of the first switching device (2H) and the second switching device (2L) is subjected to the soft turn-on.

### Appendix 9

The electronic device (A) according to Appendix 7, in which
   the control device (3) controls both the first driving device (1H) and the second driving device (1L) so that, at a timing under a state in which one of the first switching device (2H) and the second switching device (2L) has been subjected to the soft turn-on, another one of the first switching device (2H) and the second switching device (2L) is also subjected to the soft turn-on.

### Appendix 10

A vehicle (B), including the electronic device (A) according to any of Appendices 7 to 9.

### Other Modifications

Note that, the various technical features disclosed herein may be implemented in any manners other than those in the embodiments described above and allow for various modifications without departure from the spirit of their technical ingenuity. That is, the embodiments described above should be understood to be illustrative and not restrictive in every aspect. Moreover, it should be understood that the technical scope of the present disclosure is defined by the appended claims and encompasses any modifications within a scope and sense equivalent to those claims.

What is claimed is:

1. A semiconductor device, comprising:
a drive circuit configured to perform one of turn-on and turn-off of a switching device to be driven at a time of normal driving; and
an active discharge circuit configured to perform one of soft turn-on and soft turn-off of the switching device more mildly than the one of the turn-on and the turn-off by the drive circuit at a time of active discharge.

2. The semiconductor device according to claim 1, wherein
the drive circuit includes
a first transistor configured to perform one of establishment and blocking of conduction between an application terminal for a first voltage and a first external terminal, and
a second transistor configured to perform one of establishment and blocking of conduction between an application terminal for a second voltage and a second external terminal,
the active discharge circuit includes
a third transistor configured to perform one of establishment and blocking of conduction between the application terminal for the second voltage and a third external terminal, and
a fourth transistor configured to perform one of establishment and blocking of conduction between the application terminal for the first voltage and a fourth external terminal.

3. The semiconductor device according to claim 2, wherein
the first external terminal and the second external terminal are the same external terminal, and
the third external terminal and the fourth external terminal are the same external terminal.

4. The semiconductor device according to claim 1, wherein
the semiconductor device
accepts a first input pulse signal and a second input pulse signal, and
drives the switching device according to combinations of respective logic levels of the first input pulse signal and the second input pulse signal.

5. The semiconductor device according to claim 1, further comprising:
a first chip configured to allow an input pulse signal to be input to the first chip;
a second chip in which the drive circuit and the active discharge circuit are integrated; and
a third chip in which a first insulation device and a second insulation device are integrated, wherein
the first chip
indicates, to the second chip via the first insulation device, that the input pulse signal is at a logic level for turning on the switching device, and
indicates, to the second chip via the second insulation device, that the input pulse signal is at a logic level for turning off the switching device.

6. The semiconductor device according to claim 5, wherein
the first chip drives
one of the first insulation device and the second insulation device in a first drive cycle at the time of the normal driving, and drives
one of the first insulation device and the second insulation device in a second drive cycle at the time of the active discharge, and
the second chip distinguishes between the normal driving and the active discharge according to a corresponding one of the first drive cycle and the second drive cycle of one of the first insulation device and the second insulation device.

7. An electronic device, comprising:
a first switching device and a second switching device that form a half-bridge output stage by being connected in series between an application terminal for a first supply voltage and an application terminal for a second supply voltage;
a capacitor connected in parallel to the half-bridge output stage between the application terminal for the first supply voltage and the application terminal for the second supply voltage;
a first driving device configured to drive the first switching device;
a second driving device configured to drive the second switching device; and
a control device configured to control the first driving device and the second driving device, wherein
the first driving device and the second driving device are each the semiconductor device according to claim 1.

8. The electronic device according to claim 7, wherein
the control device controls both the first driving device and the second driving device so that, at a timing under a state in which one of the first switching device and the second switching device has been subjected to the soft turn-off, another one of the first switching device and the second switching device is subjected to the soft turn-on.

9. The electronic device according to claim 7, wherein
the control device controls both the first driving device and the second driving device so that, at a timing under a state in which one of the first switching device and the second switching device has been subjected to the soft turn-on, another one of the first switching device and the second switching device is also subjected to the soft turn-on.

10. A vehicle, comprising the electronic device according to claim 7.
